(19) United States
(12) Patent Application Publication
(10) Pub. No.: US 2022/0046808 A1
(43) Pub. Date: Feb. 10, 2022

(54) METHOD OF MANUFACTURING CIRCUIT BOARD AND LAMINATE

(71) Applicant: Panasonic Intellectual Property Management Co., Ltd., Osaka (JP)

(72) Inventor: Takatoshi ABE, Osaka (JP)

(73) Assignee: Panasonic Intellectual Property Management Co., Ltd., Osaka (JP)

(21) Appl. No.: 17/392,574

(22) Filed: Aug. 3, 2021

Related U.S. Application Data
(60) Provisional application No. 63/062,966, filed on Aug. 7, 2020.

(51) Int. Cl. H05K 3/46; H05K 3/00; H05K 3/10; H05K 3/24

(52) U.S. Cl. CPC H05K 3/4644; H05K 3/0011; H05K 2203/0502; H05K 3/24; H05K 3/10

(57) ABSTRACT

The present invention relates to a method of manufacturing a circuit board, which includes the steps of preparing an insulating substrate (A), fowling a polymer layer (B) containing a water-soluble polymer on at least one surface of the insulating substrate, forming a groove (C) in the polymer layer (B), forming a circuit pattern (E) in the groove (C) with use of a conductive material (D), and removing the polymer layer (B) with use of an aqueous solvent (F).

### CROSS-REFERENCE TO RELATED APPLICATIONS

This application claims the benefit of U.S. Applications No. 63/062966 filed on Aug. 7, 2020, which is incorporated herein by reference in its entirety.

### FILED OF THE INVENTION

The present invention relates to a method of manufacturing a circuit board and a laminate.

### BACKGROUND OF THE INVENTION

As a method of manufacturing a circuit board, there is known a method of forming an electric circuit on an insulating base material by a subtractive method, an additive method, or the like. The subtractive method is a method of forming an electric circuit by removing (subtracting) a metal foil other than a portion of a surface of a metal-foil-clad laminate sheet where an electric circuit is to be formed. The additive method is a method of forming an electric circuit by applying electroless plating only to a portion where a circuit is to be formed on an insulating base material.

The subtractive method is a method of etching the metal foil on the surface of the metal-foil-clad laminate sheet to leave the metal foil only at a portion where an electric circuit is to be formed and to remove the other portion. As a method of leaving the metal foil only in a desired portion, a photoresist layer and a photomask may be used, but for example, in a method disclosed in Patent Document 1 (JP H06-237063 A), ink is sprayed onto a substrate by an inkjet method to form an ink pattern to be a desired resist.

In any case, in the subtractive method, a copper foil in a portion other than the portion for forming the circuit is removed by etching, and the metal in the portion to be removed is wasted, which is disadvantageous in terms of manufacturing cost and the like. Furthermore, the etching is performed with an etching solution such as an alkaline aqueous solution or an organic solvent, which is harmful to the environment.

In addition, as a means for forming a circuit pattern, the method disclosed in Patent Document 1 requires a special device such as an inkjet, and resist ink also requires adjustment of a solid content, viscosity, and the like, which is technically difficult.

The present invention has been made in view of such circumstances, and an object of the present invention is to provide a method of manufacturing a circuit board easily and at low cost without use of a mask, an inkjet device, and a harmful etching solution.

### SUMMARY OF THE INVENTION

A method of manufacturing a circuit board according to an aspect of the present invention includes the steps of preparing an insulating substrate (A), forming a polymer layer (B) containing a water-soluble polymer on at least one surface of the insulating substrate, forming a groove (C) in the polymer layer (B), forming a circuit pattern (E) in the groove (C) with use of a conductive material (D), and removing the polymer layer (B) with use of an aqueous solvent (F).

Furthermore, a laminate for a circuit board according to another aspect of the present invention includes an insulating substrate (A), and a polymer layer (B) laminated on the insulating substrate (A) and containing a water-soluble polymer having solubility in an aqueous solvent (F).

### BRIEF DESCRIPTION OF THE DRAWING

FIG. 1 is a schematic view illustrating an example of a method of manufacturing a circuit board according to the present embodiment.

### DESCRIPTION OF EMBODIMENTS

Hereinafter, an embodiment of the present invention will be described, but the present invention is not limited to the embodiment.

As described above, a method of manufacturing a circuit board according to the present embodiment includes the steps of preparing an insulating substrate (A), forming a polymer layer (B) containing a water-soluble polymer on at least one surface of the insulating substrate, forming a groove (C) in the polymer layer (B), forming a circuit pattern (E) in the groove (C) with use of a conductive material (D), and removing the polymer layer (B) with use of an aqueous solvent (F).

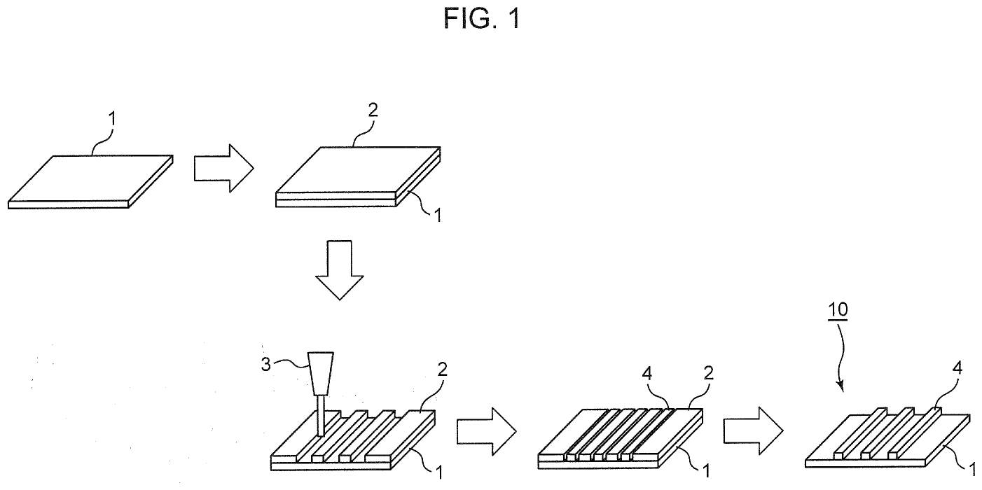

An outline of the manufacturing method according to the present embodiment will be described with reference to FIG. 1. First, an insulating substrate 1 is prepared. Then, a polymer layer 2 is formed on at least one surface of the insulating substrate 1. Thereafter, a groove is formed in the polymer layer 2 using, for example, a laser 3 or the like. Then, a conductive circuit is formed in the groove with use of a conductive material 4, and then the polymer layer 2 is removed with use of an aqueous solvent, and thus a circuit board 10 can be obtained.

In such a method of manufacturing a circuit board according to the present embodiment, the polymer layer (B) can be dissolved in an aqueous solvent such as water and removed, and thus the circuit board can be easily manufactured at low cost without use of a mask, an inkjet device, and a harmful etching solution. Further, the groove (C) having a desired shape of the circuit pattern (E) can be formed in the polymer layer (B) in the present embodiment with use of a laser or the like. Thus, for example, by designing the circuit pattern with a personal computer or the like and using digital data, the circuit pattern (E) can be designed or changed (specification change) significantly simply and accurately, which is extremely useful for industrial use.

Hereinafter, each step will be described more specifically. (Preparation of insulating substrate (A))

As the insulating substrate (A) in the present embodiment, a rigid substrate, a flexible substrate, or a stretchable substrate having stretchability can be used without particular limitation as long as the substrate is an insulating substrate used as a circuit board.

For example, as a rigid substrate or a flexible substrate, a polyethylene terephthalate (PET) film, a polyethylene naphthalate (PEN) film, a polyimide (PI) film, a polyphenylene sulfide (PPS) film, a thermoplastic polyurethane (TPU) film, a fiber-reinforced substrate such as FR4, or the like can be used.

Examples of a stretchable substrate include a stretchable substrate having a tensile elastic modulus at 25° C. of 0.5 MPa or more and/or a breaking elongation (elongation rate until breaking) of about 50% or more and about 1,000% or less.

The tensile elastic modulus and the breaking elongation are values measured by the following method:

First, a cured product of a resin composition constituting a stretchable substrate is cut into a dumbbell No. 6 (JIS K 6251, 2017) and attached to a universal testing machine (AGS-X manufactured by Shimadzu Corporation). Then, a test is performed at room temperature (25° C.) and a tensile speed of 25 mm/min, and a slope of r-σ is obtained from all stress (a) data corresponding to a strain (r) of 0 to 0.05 with use of a least squares method to calculate an initial tensile elastic modulus.

Strain (r)=x/x0 (x is a movement distance of a gripper, and x0 is a distance between initial grippers)

Stress (σ)=F/(d·l) (F is a test force, d is a film thickness, and l is a width of a test piece) For the breaking elongation, an elongation when the stretchable substrate breaks is measured by the universal testing machine.

Preferable examples of the resin composition constituting the stretchable substrate include a composition including a resin such as an epoxy resin, a polyrotaxane resin, an isocyanate resin, a polyol resin, a hydrogenated styrene-based elastomer resin, or an acrylic acid ester copolymer resin, characterized by including an alkylene oxide-modified or divalent organic group having 2 to 5,000 carbon atoms. The resins may be used singly or in combination of two or more kinds thereof. Furthermore, the resin composition may contain various additives such as a curing agent, a curing accelerator, and a filler.

Specific examples of the resin composition constituting the stretchable substrate include a resin composition including a polyrotaxane, a thermosetting resin, and a curing agent (for example, the resin composition described in WO 2015/052853A and the like).

The stretchable substrate in the present embodiment can be formed by applying the above resin composition on a support such as a PET film in an uncured or semi-cured state, appropriately heating, pressurizing, and drying the resin composition to form a cured product, and peeling off the support. Conditions of heating, pressurizing, and drying of the resin composition can be appropriately set to preferable ranges depending on a type, content, and the like of the resin as a main component.

### (Formation of Polymer Layer (B))

In the method of manufacturing a circuit board according to the present embodiment, the polymer layer (B) is formed on at least one surface of the insulating substrate (A) as described above. The polymer layer (B) is a layer containing a water-soluble polymer, and is a layer that can be dissolved and removed by the aqueous solvent (F) described later.

The water-soluble polymer contained in the polymer layer (B) in the present embodiment is not limited as long as the water-soluble polymer exhibits solubility in the aqueous solvent (F), and is preferably a water-soluble polymer having low environmental hazard, such as polyvinyl alcohol (PVA), water-soluble acrylic, water-soluble urethane, polyvinyl pyrrolidone (PVP), gelatin, water-soluble cellulose (carboxymethyl cellulose or the like), vinyl acetate, xanthan gum, polyethylene glycol (PEG), guar gum, carrageenan, sodium alginate, corn starch, sodium chondroitin sulfate, sodium hyaluronate, cationized guar gum, carboxyvinyl polymer, polyacrylic acid, and agarose.

A method of forming the polymer layer (B) is not limited, and examples of the method include a method in which a film including the above water-soluble polymer is attached to at least one surface of the insulating substrate (A), a method in which a solution including the water-soluble polymer is applied to at least one surface of the insulating substrate (A) and then dried, a method in which a solution including the water-soluble polymer is deposited on at least one surface of the insulating substrate (A) and then dried, and a method in which a solution including the water-soluble polymer is vaporized and deposited on at least one surface of the insulating substrate (A) (so-called CVD method).

A thickness of the polymer layer (B) is also not limited, and can be appropriately set in accordance with a desired circuit pattern.

### (Formation of Groove (C))

Next, the groove (C) is formed in the polymer layer (B) on the basis of a desired shape of a circuit pattern. A method of forming the groove (C) is not limited, and the groove (C) can be formed by, for example, processing by laser, plasma, or the like or mechanical processing such as cutting. FIG. 1 illustrates the groove (C) shaped in a straight line, but a shape of the groove (C) is not limited to the straight line, and may be, for example, a curved or zigzag shape. The shape of the groove (C) is not limited to a linear shape, and may be, for example, a hole shape.

In the present embodiment, the shape of the circuit to be formed can be adjusted by the shape of the groove (C), and the thickness of the circuit can be adjusted by the thickness of the polymer layer (B).

### (Forniation of Circuit Pattern (E))

Next, the circuit pattern (E) is formed in the groove (C) with use of the conductive material (D).

The conductive material (D) used in the present embodiment preferably includes at least one of a conductive resin composition or a metal.

Examples of the conductive resin composition that can be used in the present embodiment include a conductive resin composition containing a binder resin including a thermosetting resin and/or a thermoplastic resin and conductive particles. Examples of the thermosetting resin include silicon resin, urethane resin, epoxy resin, acrylic resin, and fluororubber, and examples of the thermoplastic resin include urethane resin, various rubbers, acrylic resin, olefin-based resin, ethylene propylene diene rubber, isoprene rubber, butadiene rubber, and chloroprene rubber. In particular, in terms of heat resistance, it is preferable to use a thermosetting resin composition, more preferably an epoxy resin, a urethane resin, or a silicon resin, and still more preferably an epoxy resin.

Specific examples of the conductive particles include silver, silver-coated copper (including a configuration in which a part of a surface of copper is coated with silver), copper, gold, carbon particles, carbon nanotubes, a conductive polymer, tin, bismuth, indium, gallium, and the like, and particles including an alloy of these metals.

When a stretchable substrate is used as the insulating substrate (A), a conductive resin composition having stretchability is preferable, and for example, a silver paste or a silver ink obtained by combining a stretchable epoxy resin, an acrylic resin, a urethane resin, a silicon resin, a fluororesin, a styrene-butadiene copolymer resin with silver powder, silver flakes, or the like can be used.

One of specific examples of the stretchable conductive resin composition includes a conductive resin composition (for example, a conductive resin composition disclosed in JP 2018-35286 A and the like) in which a molecular structure includes a resin including at least one of (meth) acrylic acid ester, styrene, or acrylonitrile as a constituent element, a curing agent, and conductive particles.

The metal that can be used in the present embodiment may be a sintered body of metal particles, a liquid metal, or the like.

The sintered body is obtained by heating fine particles of silver, copper, gold, or the like at an appropriate firing temperature to melt or dissolve surfaces of the particles in a solid solution, and is obtained by printing, heating, drying, and firing a metal particle-dispersed ink in which the fine particles are dispersed in water or an organic solvent.

Examples of the liquid metal that can be used in the present embodiment include gallium alone or a gallium-indium alloy, a gallium-indium-tin alloy, and a gallium-indium-tin-zinc alloy.

A method of forming the circuit pattern (E) in the present embodiment is not limited, and for example, the circuit pattern (E) can be formed by a printing method or the like. Specifically, when the conductive material (D) is a paste or a liquid metal of a conductive resin composition, the conductive material (D) can be applied by printing to the groove (C) by a printing method such as screen printing, inkjet printing, gravure printing, or offset printing to form a circuit having a desired pattern.

When the conductive material (D) is a sintered body of metal particles, for example, the circuit pattern (E) can be formed in the groove (C) by printing an ink (metal particle-dispersed ink) including the sintered body of metal particles as described above by inkjet or the like, and then by heating, drying, and firing the ink.

In addition to the above, examples of a method of forming the circuit pattern (E) include a method of forming the circuit pattern (E) by electrolysis or electroless plating, and a method of forming the circuit pattern (E) by depositing metal.

First, a method of forming the circuit pattern (E) by electroless plating will be described specifically. A plating base (plating catalyst) is applied to the groove (C).

The plating catalyst is not limited, and any plating catalyst known as a catalyst for electroless plating can be used. The plating catalyst may be generated after a precursor of the plating catalyst is applied in advance. Specific examples of the plating catalyst include metal palladium (Pd), platinum (Pt), silver (Ag), and a precursor for producing these metals.

Examples of a method of applying the plating catalyst include a method in which the plating catalyst is treated with an acidic Pd-Sn colloidal solution treated under acidic conditions at pH 1 to pH 3, and then treated with an acid solution.

Next, by performing electroless plating, an electroless plating film is deposited on a portion of the groove (C) where the plating catalyst remains, and the circuit pattern (E) is formed.

In the present embodiment, the groove (C) is preferably completely filled with the electroless plating film. Alternatively, plating treatment is preferably performed such that the electroless plating film partially protrudes from the groove (C). Specific plating time is not limited, and can be appropriately changed in accordance with a size of the groove (C) and the like. For example, the plating treatment can be performed by immersing a substrate in an electroless plating solution for 30 minutes to 600 minutes. By setting the plating time to be longer, the groove (C) is subjected to the plating treatment (over-plating) to such a level that the electroless plating film protrudes from a surface of the polymer layer (B). A plating treatment temperature is not limited as long as it is a temperature at which metal ions such as copper ions cause a reduction reaction. However, a temperature of the plating solution is preferably set to 20° C. to 90° C. and more preferably set to 50° C. to 70° C. in terms of efficiently performing the reduction reaction.

As described above, the groove (C) is subjected to the plating treatment (over-plating) to such a level that the electroless plating film protrudes from the surface of the polymer layer (B), and a protruding portion of the plating can be appropriately removed.

As a method of an electroless plating treatment, a method can be used in which a substrate coated with a plating catalyst is immersed in an electroless plating solution, and an electroless plating film is deposited only on a portion coated with the plating catalyst.

Examples of the metal used for electroless plating include copper (Cu), nickel (Ni), cobalt (Co), and aluminum (Al). Among these metals, plating containing Cu as a main component is preferable in terms of excellent conductivity. Plating including Ni is preferable in terms of excellent corrosion resistance and adhesion to solder.

### (Removal of Polymer Layer (C))

After the circuit pattern (E) is formed as described above, the polymer layer (B) is removed, and then a circuit board having a desired circuit can be obtained. In the present embodiment, the polymer layer (B) contains a water-soluble polymer, and can be easily removed with use of an aqueous solvent (F).

The aqueous solvent (F) is not limited as long as the aqueous solvent can dissolve the water-soluble polymer constituting the polymer layer (B), and any solvent mainly composed of water is sufficient. The phrase “mainly composed of water” means that the content of water in the aqueous solvent (F) is 51% or more, and water itself may be used as the aqueous solvent (F). The aqueous solvent (F) is desirably a solvent having a low environmental load, and may be a solvent including, as a component other than water, for example, alcohol, hexane, ethyl acetate, acetic acid, tetrahydrofuran, acetone, acetonitrile, triethylamine, ethylene glycol, or the like.

A method of removing the polymer layer (B) is not limited, and examples of the method include a method in which the polymer layer (B) is dissolved by immersing the substrate in the aqueous solvent (F) and a method in which the polymer layer (B) is removed by washing away the substrate with the aqueous solvent (F).

### (Other Steps)

In addition to the above steps, the method of manufacturing a circuit board according to the present embodiment may further include at least one of applying a solder mask to the circuit pattern (E) or applying rust prevention treatment to the circuit pattern (E) in order to protect the formed circuit pattern (E). This can improve storage property of the circuit board. These steps are performed after removing the polymer layer (B) as described above.

The solder mask is applied to suppress occurrence of corrosion in the circuit pattern (E) including the conductive resin composition or metal. The solder mask can be applied by a known means with use of a general solder resist.

The rust prevention treatment is performed to suppress generation of rust in the circuit pattern (E). A method of the rust prevention treatment is not limited, and for example, the rust prevention treatment can be performed by performing aqueous preflux treatment or electroless gold plating.

In a case where both the solder mask treatment and the rust prevention treatment are performed, it is desirable to perform the rust prevention treatment after performing the solder mask treatment.

### (Laminate)

The present embodiment also includes a laminate for a circuit board including the insulating substrate (A), and the polymer layer (B) laminated on the insulating substrate (A). The polymer layer (B) contains a water-soluble polymer having solubility in the aqueous solvent (F).

The insulating substrate (A), the polymer layer (B), and the aqueous solvent (F) in the laminate in the present embodiment are identical to those described in the method of manufacturing a circuit board.

By using the laminate for a circuit board in the present embodiment, it is possible to manufacture a circuit board easily and at low cost without use of a mask, an inkjet device, and a harmful etching solution which have been required for manufacturing a conventional circuit board.

### (Specific Embodiments)

### PRODUCTION EXAMPLE 1

A PVA (manufactured by FUJIFILM Wako Pure Chemical Corporation) aqueous solution was applied to a polyimide film (UPILEX) and dried for one hour in an oven set at 80° C. to remove the aqueous solvent, and thus a PVA layer was formed. On a substrate on which the PVA layer was laminated on the obtained polyimide film, a circuit pattern was grooved in the PVA layer with a laser (output: 20 W, Speedy 100 manufactured by Trotec GmbH) to obtain a patterned substrate. A silver paste (PE 773, manufactured by DuPont de Nemours, Inc.) was printed on the groove formed in the substrate with a squeegee and dried for one hour in an oven set at 80° C. The substrate was washed with ion-exchanged water to remove the PVA layer, and moisture was sufficiently dried in an oven to obtain a flexible printed wiring board.

### PRODUCTION EXAMPLE 2

A PVA (manufactured by FUJIFILM Wako Pure Chemical Corporation) aqueous solution was applied to a PET film (Lumirror #50-X10S manufactured by Toray Industries, Inc.) and dried for one hour in an oven set at 80° C. to remove the aqueous solvent, and then a PVA layer was formed. On a substrate on which the PVA layer was laminated on the obtained polyimide film, a circuit pattern was grooved in the PVA layer with a laser (output: 20 W, Speedy 100 manufactured by Trotec GmbH) to obtain a patterned substrate. A silver complex ink (AgIC ink pen manufactured by Elephantech Inc.) was applied to the formed groove, and the ink was sintered in an oven at 100° C. for 15 minutes. The obtained ink-applied substrate was washed with water to remove the PVA layer, electroless copper plating was performed to form a circuit at a portion coated with the silver complex ink, and then a flexible printed wiring board was obtained.

In order to express the present invention, the present invention has been appropriately and sufficiently described through the embodiment with reference to the drawings, specific examples, and the like. It should be understood, however, that those skilled in the art can easily change and/or improve the embodiment. Therefore, unless a change or improvement made by those skilled in the art is at such a level as to depart from the scope of rights of the claims described in the claims, the change or improvement is interpreted to be included in the scope of rights of the claims. Industrial Applicability

The present invention has wide industrial applicability in technical fields related to a circuit board and manufacturing of the circuit board.

1. A method of manufacturing a circuit board, the method comprising the steps of:
preparing an insulating substrate (A);
forming a polymer layer (B) containing a water-soluble polymer on at least one surface of the insulating substrate;
forming a groove (C) in the polymer layer (B);
forming a circuit pattern (E) in the groove (C) with use of a conductive material (D); and
removing the polymer layer (B) with use of an aqueous solvent (F).

2. The method of manufacturing a circuit board according to claim 1, wherein the conductive material (D) includes at least one of a conductive resin composition or a metal.

3. The method of manufacturing a circuit board according to claim 1, comprising, after removing the polymer layer (B) with use of the aqueous solvent (F), at least one step of applying a solder mask to the circuit pattern (E) or applying a rust prevention treatment to the circuit pattern (E).

4. A laminate for a circuit board, the laminate comprising:
an insulating substrate (A); and
a polymer layer (B) laminated on the insulating substrate (A) and containing a water-soluble polymer having solubility in an aqueous solvent (F).
